(19) United States
(12) Patent Application Publication
(10) Pub. No.: US 2016/0056092 A1
(43) Pub. Date: Feb. 25, 2016

(54) Leadframe and method of manufacturing the same

(71) Applicant: Infineon Technologies Austria AG, Villach (AT)

(72) Inventors: Ralf OTREMBA, Kaufbeuren (DE); Chooi Mei CHONG, Melaka (MY); Josef HOEGLAUER, Heimstetten (DE); Teck Sim LEE, Melaka (MY); Klaus SCHIESS, Allensbach (DE); Xaver SCHLOEGEL, Sachsenkam (DE)

(21) Appl. No.: 14/830,548

(22) Filed: Aug. 19, 2015

(30) Foreign Application Priority Data
Aug. 20, 2014 (DE) 10 2014 111 908.8

(51) Int. Cl. H01L 23/495; B23K 20/02; B23K 1/00; B23K 1/19; H01L 21/48; H01L 25/065

(52) U.S. Cl. CPC H01L 23/49503; H01L 23/49541; H01L 23/49582; H01L 21/4828; H01L 23/49575; H01L 25/0655; H01L 21/4842; H01L 21/4821; B23K 1/0008; B23K 1/19; B23K 20/02; B23K 2203/12

(57) ABSTRACT

A hybrid leadframe is provided comprising a thin leadframe layer comprising a diepad and a structured region; and a metal layer being thicker than the thin leadframe layer and arranged on the diepad.

### TECHNICAL FIELD

Various embodiments relate to a leadframe, in particular a hybrid leadframe comprising two sub-layers and a method of manufacturing the same.

### BACKGROUND

In the prior art a plurality of packaged chips or electronic modules are known. One example of such packaged chip are so called power packages, i.e. packaged electronic modules intended to carry, conduct or switch electrical power signals or voltages which are higher than the signal level of common information signals. In such power packages chip backside redistribution (drain/collector-contact) is typically done by leadframe soldering while the chip frontside redistribution (source/emitter- and gate-contact) will be done by wire bonding and/or clip bonding.

The leadframe is typically used for electrical (via the leads) and thermal (diepad) redistribution of the chips or dies and is typically structured within a manufacturing process like punching or etching.

### SUMMARY

Various embodiments provide a hybrid leadframe comprising a thin leadframe layer comprising a diepad and a structured region; and a metal layer being thicker than the thin leadframe layer and arranged on the diepad.

Furthermore, various embodiments provide a method of manufacturing a hybrid leadframe, wherein the method comprises providing a thin leadframe layer comprising a diepad and a structured region; and attaching a metal layer on the diepad, wherein the metal layer has a thickness which is larger than a thickness of the thin leadframe layer.

Moreover, various embodiments provide a power package comprising a hybrid leadframe according to an exemplary embodiment; and a chip arranged on the metal layer.

### BRIEF DESCRIPTION OF THE DRAWINGS

In the drawings, like reference characters generally refer to the same parts throughout the different views. The drawings are not necessarily to scale. Instead emphasis is generally being placed upon illustrating the principles of the invention. In the following description, various embodiments are described with reference to the following drawings, in which:

FIGS. 1A and 1B schematically show exemplary embodiments of power packages comprising a hybrid leadframe;

FIGS. 2A to 2D schematically show a process of manufacturing a hybrid leadframe according to an exemplary embodiment;

FIGS. 3A to 3G schematically show a process of manufacturing a power package according to an exemplary embodiment; and

FIGS. 4A to 4E schematically show exemplary embodiments of power packages.

### DETAILED DESCRIPTION

In the following further exemplary embodiments of a hybrid leadframe, a method of manufacturing a hybrid leadframe, and a power package comprising a hybrid leadframe will be explained. It should be noted that the description of specific features described in the context of one specific exemplary embodiment may be combined with others exemplary embodiments as well.

The word “exemplary” is used herein to mean “serving as an example, instance, or illustration”. Any embodiment or design described herein as “exemplary” is not necessarily to be construed as preferred or advantageous over other embodiments or designs.

Various exemplary embodiments provide hybrid leadframes and methods of manufacturing such hybrid leadframes, wherein the hybrid leadframe comprises two sub-layers (formed from different or the same materials) preferably formed by different processes and having different thicknesses, and stacked on top of each other, in particular by attaching one sub-layer, e.g. an (unstructured) metal layer on the other sub-layer, e.g. a thin leadframe layer (e.g. comprising a diepad and a structured region or area), so that a hybrid leadframe is formed comprising two distinguishable sub-layers. For example, the metal layer is only arranged on the diepad of the thin leadframe layer.

Furthermore, a power package comprising one or more hybrid leadframes may be provided wherein at least one chip or die is attached or arranged on the metal layer of the hybrid leadframe. In particular, a plurality of chips or dies may be arranged on the metal layer. Alternatively or additionally an additional metal layer may be arranged on the diepad, wherein on the additional metal layer an additional chip is arranged. For example, the chip may be attached to the diepad, e.g. by an adhesive process like soldering or using an adhesive paste or adhesive film or the like.

In particular, the metal layer is only arranged on or attached to the diepad and/or the structured region is free of the metal layer. For example, the diepad may have a first size or area while the metal layer may have a second size or area, which is larger, thus leading to a metal layer “overhanging” the diepad or diepad region of the thin leadframe layer. Alternatively, the second size or area of the metal layer may be smaller than the first size of the diepad thus leading to an “overhanging” of the diepad region. The metal layer may form or function as a kind of shim or spacer of the hybrid leadframe.

The term “diepad” may particular denote an area or region of the thin leadframe which is adapted to receive a chip or die afterwards and which may be unstructured, e.g. forming a planar area or region.

By providing a hybrid leadframe comprising two layers or two sub-layer it may be possible to separate the functions of a typical hybrid leadframe. While the thin leadframe layer may be used for electrical redistributing the thicker metal layer may function as a thermal puffer or as a thermal redistribution layer. In particular, it may be possible (due to the use of a thin leadframe layer) to provide leads of the hybrid leadframe having a small pitch, e.g. in the order of the thickness of the hybrid leadframe, for example even below 1 mm, in particular below 0.4 mm, e.g. in the range of 0.1 mm or 0.2 mm to 0.4 mm.

Thus, it may be possible to adapt the hybrid leadframe more closely to specific needs of an electronic module or power package the hybrid leadframe is used in. In addition, it may be possible to use different manufacturing processes for the two sub-layers of the hybrid leadframe, e.g. etching and stamping, sawing or the like which may additionally increase flexibility and at the same time may reduce manufacturing costs. In addition, it may be possible to adapt or adjust a height of the hybrid leadframe in a simple and efficient way by just adapting or adjusting a height of the metal layer. Thus, it may be possible to adjust the total height of the hybrid leadframe in an efficient way to standard dimensions which are typically used for clip bondings or the like.

It should be noted that attaching a metal layer has to be understand in a broad sense and the sequence of described steps does not limit a method to a timely sequence of the steps. For example, at first a metal layer may be provided and then the thin leadframe layer may be attached to the metal layer.

By providing such a hybrid leadframe it may be possible to combine advantages of different materials and or forming processes of the two sub-layers. For example, a common thin leadframe layer may be formed by an etching process, suitable for fulfilling flexible design rules, while the metal layer, e.g. an unstructured metal block, may be formed in a less complex and expensive stamping or punching process, which is suitable for thicker layers as well. Thus, a redistribution concerning electrical functions may be performed by one sub-layer (thin leadframe layer) while a redistribution concerning thermal functions (e.g. thermal buffering function) may be (primarily) provided by a second sub-layer, e.g. a thicker metal (copper) layer.

In the following exemplary embodiments of the hybrid leadframe are described. However, the features and elements described with respect to these embodiments can be combined with exemplary embodiments of the power package and the method of manufacturing a hybrid leadframe.

According to an exemplary embodiment of the hybrid leadframe the metal layer is an unstructured metal block.

The term “unstructured” may particularly denote that no electric connection lines, connection pads or the like are patterned or formed on or in the unstructured portion, e.g. the unstructured metal block. Thus, the unstructured metal block forms no portion or part of an electrical redistribution but only part of the thermal redistribution. However, alternatively the metal layer may be structured as well and thus may additionally useful for some amount of electrical redistribution as well.

According to an exemplary embodiment of the hybrid leadframe the metal layer comprises copper as a material.

In particular, the metal layer may consist substantially of copper. In general copper may be, due to its high thermal conductivity and heat capacity, a good choice for thermal redistributing. Alternatively aluminum or even iron-nickel alloys may be used for the metal layer.

According to an exemplary embodiment of the hybrid leadframe the metal layer is attached to the thin leadframe layer by an adhesive process.

In particular, the adhesive process may be a soldering process or a process wherein an adhesive paste, film or material is used. In general, every process may be used which is suitable for attaching the metal layer to the thin leadframe layer.

According to an exemplary embodiment of the hybrid leadframe the adhesive process is a diffusion soldering process.

The diffusion soldering process or hybrid leadframe diffusion soldering process may be in particular useful, since in such a diffusion soldering process a layer of material may be applied or plated onto the hybrid leadframe wherein the material of the plated layer has a melting temperature lower than the alloy resulting from a diffusion of the plating material and the one of the thin leadframe layer. Thus, it may be possible that the metal layer can be attached or fixed to the thin leadframe layer at a relative low temperature (melting temperature of the plating material) while after forming of the alloy the hybrid leadframe can be processed at the same low temperature or a higher temperature (up to the melting temperature of the alloy) afterwards without risking the melting of the alloy afterwards.

According to an exemplary embodiment of the hybrid leadframe the thin leadframe layer is a dual gauge leadframe layer.

In particular, the thin leadframe layer may have a greater thickness in the region of the diepad, while at the same time having a thinner thickness in the structured region (e.g. forming the leads of the hybrid leadframe). Thus, it may be possible that already the thin leadframe layer forms part of a thermal redistribution or thermal buffering, while the thinner portions (structured region) may be flexibly structured.

According to an exemplary embodiment of the hybrid leadframe the thin leadframe layer is structured by an etching process.

In particular, the thin leadframe layer may be a so called half-etch hybrid leadframe, i.e. a hybrid leadframe being etched from one side (one main surface) and preferably not etched from the opposite side. By using an etching process for structuring the thin leadframe layer it may be possible to match or observe in a very flexible way design rules for the total or hybrid leadframe.

According to an exemplary embodiment of the hybrid leadframe the metal layer is formed by a stamping process.

In particular, a stamping or punching process is a suitable and efficient process to form an unstructured metal layer or metal block. In particular, stamping or punching is a low complex process for forming thick layers or structures in an efficient way.

In the following exemplary embodiments of the method of manufacturing a hybrid leadframe are described. However, features described with respect to these embodiments can be combined with exemplary embodiments of the hybrid leadframe and the power package.

According to an exemplary embodiment of the method the thin leadframe layer is structured by an etching process.

According to an exemplary embodiment of the method the metal layer is formed by a stamping process.

According to an exemplary embodiment of the method the attaching of the metal layer is performed by a diffusion soldering process.

However, any suitable attaching process like common soldering processes or adhesive processes may be used as well.

According to an exemplary embodiment of the method the attaching of the metal layer to the thin leadframe layer is performed in a batch process.

In particular, a plurality of metal layers and thin leadframe layers may be provided and a plurality of thin leadframe layers and a plurality of metal layer, respectively may be attached to each other simultaneously or at the same time in a batch process. For example, the attachment may be performed by a hybrid leadframe diffusion soldering batch process.

In the following exemplary embodiments of the power package are described. However, features described with respect to these embodiments can be combined with exemplary embodiments of the hybrid leadframe and the method of manufacturing the same.

According to an exemplary embodiment the power package further comprising a further chip which is arranged directly on the diepad.

That is, the further chip or die may be directly arranged on or attached to the diepad, i.e. not arranged on the metal layer but arranged directly on the diepad of the thin leadframe layer. This direct arranging may be suitable in case the further chip typically generate less heat during operation so that the heat capacity of the metal layer is not as necessary as for the chip arranged on the metal layer, which is in particular a power chip. In particular, the chip and/or the further chip may be a transistor, in particular a power transistor, i.e. a transistor adapted to switch signal having a voltage level of more than 50 V, for example.

According to an exemplary embodiment the power package further comprising an encapsulation comprising a molding material.

In particular, the encapsulation may be formed by a molding process, e.g. a cavity molding process, optionally combined with a later punching singulation, or a map molding process, optionally combined with a later sawing singulation.

In the following specific embodiments of the hybrid leadframe will be described in more detail with respect to the figures.

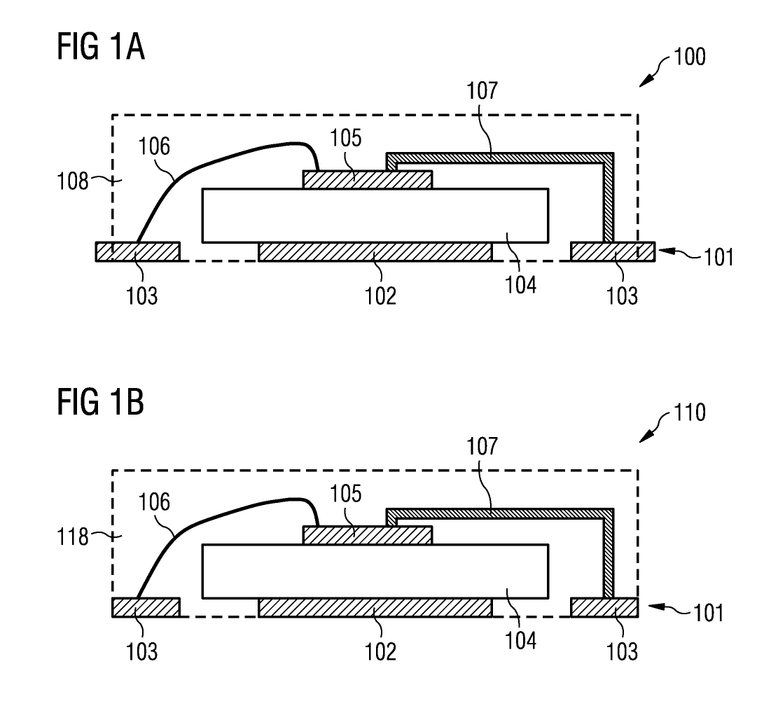

FIGS. 1A and 1B schematically show exemplary embodiments of power packages comprising a hybrid leadframe. In particular, FIG. 1A shows a power package 100 comprising a thin leadframe layer 101 comprising a diepad 102 and structured regions 103 forming leads of the thin leadframe layer 101. Furthermore, the power package 100 comprises a thick metal layer or metal block 104 attached to the diepad 102, e.g. by any adhesive or soldering process. Onto the metal layer a chip or die 105 is arranged or attached having contact pads (not shown) arranged on the upper side.

For example, in case a (power) transistor forms the chip the contact pads may be electrically connected to source/emitter and/or gate contacts of the transistor, while the lower or bottom side connected to the metal layer may form a drain/collector contact. The contact pads of the upper side may be connected via wirebonding 106 or clips 107 to the structured regions 103 of the thin leadframe layer. Furthermore, an encapsulation or molding compound 108 is shown in FIG. 1A encapsulating the described components. For example, the encapsulation may be formed by a cavity molding process and an later punching singulation (as indicated by leads 103 extending sideways out of the encapsulation 108.

FIG. 1B in contrast schematically show a power package 110 having an encapsulation 118 which is formed by a map molding process and a later sawing singulation, as indicating by the fact that leads 113 do not extend sideways out of the encapsulation 118. The other components of the power package 110 are identical to the one of FIG. 1A and are not described again due to this reason.

A thickness of the thin leadframe layer 101 of the embodiments of FIGS. 1A and 1B may be in the range of 100 micrometer to 300 micrometer (particularly about 200 micrometer) while a thickness of the metal layer 104 may be in the range of 600 micrometer and 1000 micrometer (particularly about 800 micrometer). In general a ratio of the thicknesses of the thin leadframe layer and the metal layer may be in the range of 1:2, to 1:10, for example. In particular, the metal layer may comprise or may consist of copper. Alternatively aluminum or an alloy of iron and nickel may be used as well.

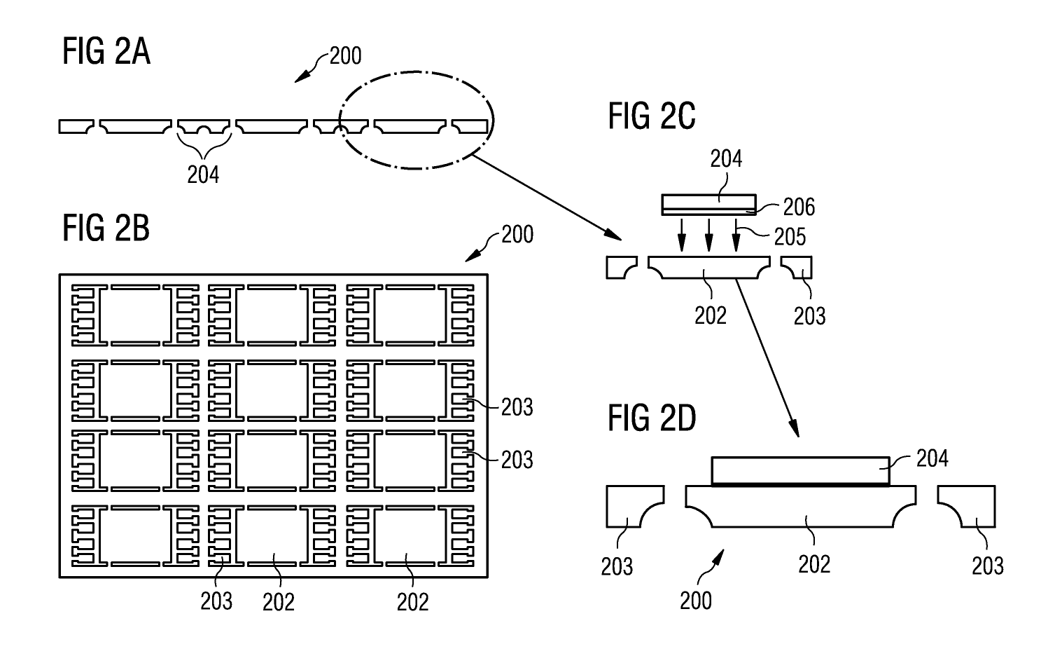

FIGS. 2A to 2D schematically show a process of manufacturing a hybrid leadframe according to an exemplary embodiment. In particular, FIG. 2A shows standard half-etch leadframes 200 in a side view having etched structures on one side (lower side in FIG. 2A) as indicated in FIG. 2A by “half circle” or “half elliptic” structures 201. FIG. 2B shows the leadframe 200 of FIG. 2A in a plan view and showing diepads 202 and leads 203.

FIG. 2C shows a single thin leadframe layer 200 of FIG. 2C wherein a metal block, e.g. a stamped copper block or plate, 204 is attached to the leadframe 200, which is indicated by the arrows 205. In addition, an additional solder layer or plating 206 is shown in FIG. 2C which is plated or arranged on the metal block 204 and is intended to facilitate or improve an attachment of the metal block 204 to the thin leadframe layer 200, e.g. in case of diffusion soldering a CuSn plating may be used.

FIG. 2D shows the leadframe 200 of FIG. 2C after finishing the diffusion soldering process shown in FIG. 2C. In particular, the process or method of FIG. 2 describes basic steps of a process enabling the manufacturing of a kind of dual gauge hybrid leadframe having two sub-layers and possibly providing for a good heat spreading. In addition the use of a half-etch leadframe may enable the use of map molding or cavity molding and may decouple footprint from diepad areas or regions.

In the context of FIG. 2 and the following figures it should be noted that while the metal layer is always shown to be thinner than the respective leadframe in general the metal layer is thicker than the respective leadframe.

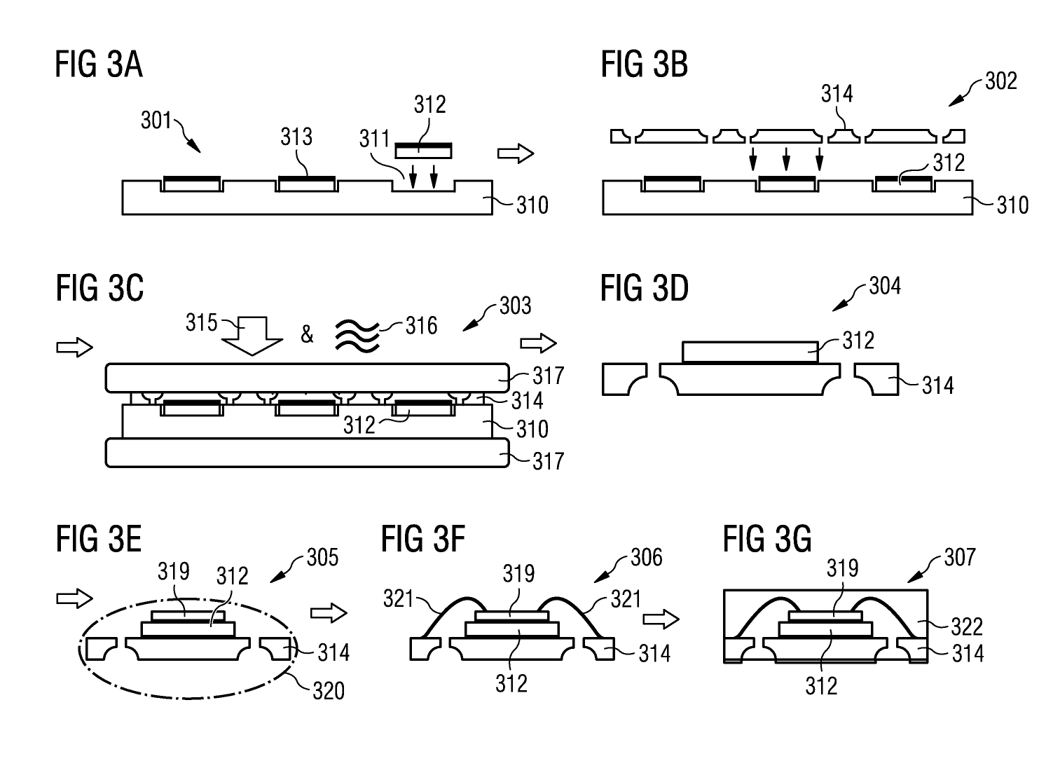

FIGS. 3A to 3G schematically show a process of manufacturing a power package according to an exemplary embodiment. In particular, FIG. 3A shows a first step 301 of a batch process of manufacturing hybrid leadframes, in which first step a carrier 310 is provided comprising a plurality of reception areas 311 for respective metal (copper) layers 312 comprising a plated layer 313 attached thereto. After the metal layers 312 are arranged in the reception areas a leadframe 314 is arranged above the carrier 310 and put on the same as indicated in FIG. 3B as step 302. For example, the leadframe 314 may be one as shown in FIG. 2B comprising diepad areas and structured areas or regions (forming leads).

In a next step (FIG. 3C) a diffusion soldering process 303 is performed by applying pressure (indicated by arrows 315) and heat (indicated by sinuous lines 316) to the two sub-layers (metal layer and leadframe) in a press (indicated by the layers 317). Afterwards the ready hybrid leadframe 318 can be removed from the carrier 310 (FIG. 3D).

In the FIG. 3E to 3G further steps of forming a power package from the leadframe 318 are shown. In particular, FIG. 3E shows the leadframe 318 after a chip or die 319 is attached to the metal layer 312 so that a chip arrangement 320 is formed (step 305). FIG. 3F shows the chip arrangement 320 after contact pads of the chip 319 are electrically connected to the leads via wire bonding 321. Afterwards an encapsulation 322 comprising a molding material is formed onto the chip arrangement of FIG. 3F as indicated in FIG. 3G (step 307).

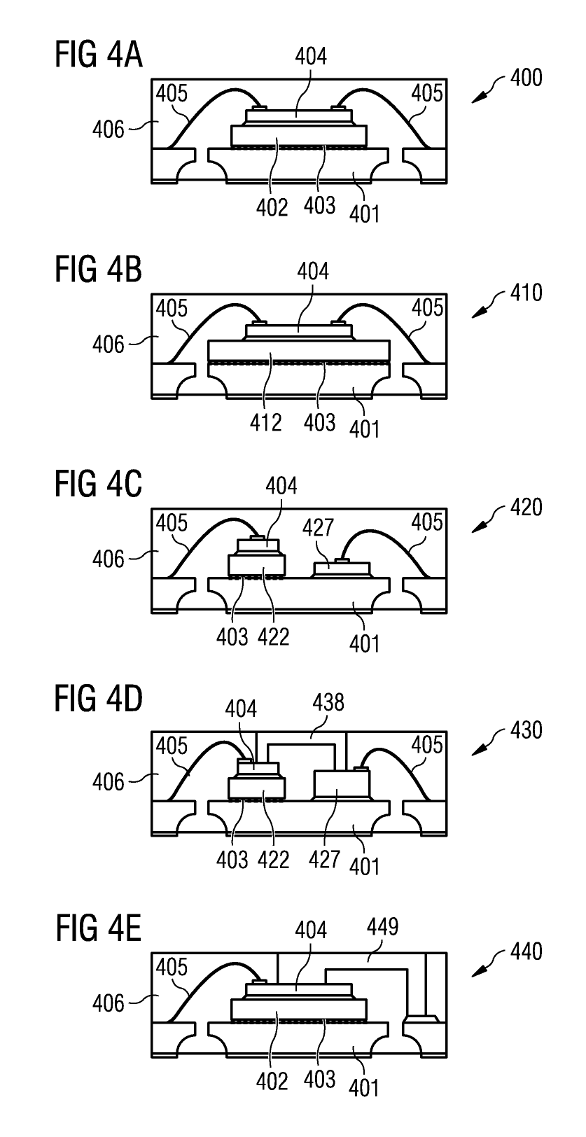

FIGS. 4A to 4E schematically show exemplary embodiments of power packages. In particular, FIG. 4A shows a first power package 400 according to a first exemplary embodiment, comprising a thin leadframe layer 401 and a metal layer 402 attached thereto by a soldering step or layer (indicated as 403 in FIG. 4A), wherein the metal layer 402 has a smaller size as a diepad of the thin leadframe layer 401 so that the thin leadframe layer “overhangs” the metal layer 402. Furthermore, the power package 400 comprises a power chip or power die 404 which is electrically connected to leads of the thin leadframe layer 401 via bonding wires 405. In addition an encapsulation 406 is shown in FIG. 4A.

In particular, FIG. 4B shows a second power package 410 according to a second exemplary embodiment, which is similar to the one shown in FIG. 4A. However, the size of a respective metal layer 412 is of the same size as a diepad of a respective thin leadframe layer 401, so that neither the metal layer nor the thin leadframe layer overhangs the respective other sub-layer of a hybrid leadframe. The other components are identical to the one of the first embodiment shown in FIG. 4A and are not described again.

In particular, FIG. 4C shows a third power package 420 according to a third exemplary embodiment, which is similar to the one shown in FIG. 4A. However, the size of a respective metal layer 422 is much smaller than the one of a diepad of a respective thin leadframe layer 401. Thus, leading to the fact that enough space is available on the diepad that another chip or die 427 can be arranged on the diepad. As indicated in FIG. 4C no additional metal layer is formed between the diepad and the another chip 427. This may be advantageous in case the another chip does not provide a high amount of heat, e.g. because it is not a power chip. In case the another chip 427 is as well a power chip an additional metal layer may be formed beneath the another chip or the metal layer 422 may be formed having a sufficient size for the another chip 427 as well.

In particular, FIG. 4D shows a fourth power package 430 according to a fourth exemplary embodiment, which is similar to the one shown in FIG. 4C. However, an additional clip connection 438 is formed between a chip 404 and another chip 427 connection the two chips which each other.

In particular, FIG. 4E shows a fifth power package 440 according to a fifth exemplary embodiment, which is similar to the one shown in FIG. 4A. However, compared to the one shown in FIG. 4A one of the bonding wires 405 is replaced by a clip connection 449.

Summarizing an exemplary aspect of various exemplary embodiments may be seen in manufacturing and providing a hybrid leadframe comprising two sub-layers which are distinguishable from each other. In particular, the two sub-layers may be optimized with respect to different functions. For example, a thin (half-etched) leadframe layer may take over the function of an electrical redistribution while a thicker (stamped) metal layer or block may take over the function of a thermal redistribution. Furthermore, the metal layer may as well be advantageous with respect to adapt a height of a diepad of the hybrid leadframe to enable use of standard clip thickness material. Thus, it may be possible to use standard leadframe material thickness and standard clip material thickness so that the whole process may be less costly compared to a process where no adaption metal layer is used so that a combination of die thickness and package thickness would require non-standard clip material thickness.

It should be noted that the term “comprising” does not exclude other elements or features and the “a” or “an” does not exclude a plurality. Also elements described in association with different embodiments may be combined. It should also be noted that reference signs shall not be construed as limiting the scope of the claims. While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A hybrid leadframe comprising:
a thin leadframe layer comprising a diepad and a structured region; and
a metal layer being thicker than the thin leadframe layer and arranged on the diepad.

2. The hybrid leadframe according to claim 1,
wherein the metal layer is an unstructured metal block.

3. The hybrid leadframe according to claim 1, wherein the metal layer comprises copper as a material.

4. The hybrid leadframe according to claim 1, wherein the metal layer is attached to the thin leadframe layer by an adhesive process.

5. The hybrid leadframe according to claim 4, wherein the adhesive process is a diffusion soldering process.

6. The hybrid leadframe according to claim 1, wherein the thin leadframe layer is a dual gauge leadframe layer.

7. The hybrid leadframe according to claim 1, wherein the thin leadframe layer is structured by an etching process.

8. The hybrid leadframe according to claim 1, wherein the metal layer is formed by a stamping process.

9. A method of manufacturing a hybrid leadframe, the method comprising:
providing a thin leadframe layer comprising a diepad and a structured region;
attaching a metal layer on the diepad, wherein the metal layer has a thickness which is larger than a thickness of the thin leadframe layer.

10. The method according to claim 9, wherein the thin leadframe layer is structured by an etching process.

11. The method according to claim 9, wherein the metal layer is formed by a stamping process.

12. The method according to claim 9, wherein the attaching of the metal layer is performed by a diffusion soldering process.

13. The method according to claim 9, wherein the attaching of the metal layer to the thin leadframe layer is performed in a batch process.

14. A power package comprising:
a hybrid leadframe according to claim 1; and
a chip arranged on the metal layer.

15. The power package according to claim 14, further comprising a further chip which is arranged directly on the diepad.

16. The power package according to claim 14, further comprising an encapsulation comprising a molding material.
